(19) United States
(12) Patent Application Publication
(10) Pub. No.: US 2005/0106824 A1
(43) Pub. Date: May 19, 2005

(54) Method for suppressing transient enhanced diffusion of dopants in silicon

(76) Inventors: Carnera Alberto, Mestre (IT); Coati Alessandro, Paris (FR); De Salvador Davide, Belluno (IT); Mirabella Salvatore, S.A. Li Battiati (IT); Napolitani Enrico, Padova (IT); Priolo Francesco, Catania (IT); Scalese Silvia, Cosenza (IT)

Correspondence Address: SUGHRUE MION, PLLC, 2100 PENNSYLVANIA AVENUE, N.W., SUITE 800, WASHINGTON, DC, 20037, US

(21) Appl. No.: 10/497,501

(22) PCT Filed: Dec. 3, 2002
(86) PCT No.: PCT/EP02/13659

(30) Foreign Application Priority Data
Dec. 4, 2001 (IT) TO2001A001129

(51) Int. Cl. H01L 21/336; H01L 21/04; H01L 21/425

(52) U.S. Cl. 438/301; 438/303; 438/528

(57) ABSTRACT

Method for suppressing the transient enhanced diffusion (TED) of a dopant implanted in a thin surface layer of a semiconductor substrate, the TED being normally caused by the interaction between the dopant and the lattice damage caused by the implantation of the dopant itself or by pre-amorphization implantations during the post-implantation annealing thermal process. The aforesaid heat treatment is carried out on a crystalline semiconductor having an amorphous surface layer in which the dopant is implanted and having a layer rich in a trap element which effectively traps self-interstitial point defects. The layer rich in a trap element is spatially separated from the dopant-rich surface layer and is interposed between the dopant-rich surface layer and the interface between the amorphous and crystalline regions of the substrate.

The present invention relates in a general way to a process for the industrial production of semiconductors and more particularly to a method for treating semiconductors in order to suppress the transient enhanced diffusion (TED) caused by the interaction between the dopant and the damage to the lattice due to the implantation, this diffusion occurring during the thermal process of post-implantation annealing.

The development of microelectronics has been stimulated and accompanied by a reduction in the size of elementary devices. Continuing the trend described in the last thirty years by the well-known Moore's Law, the Roadmap drawn up by the Semiconductor Industry Association [Road] requires the production, in the near future, of silicon devices having electrical junctions with depths of less than 30 nm, for which no effective manufacturing methods have yet been found [Road].

Ion implantation is, and will probably continue for a long time to be, the preferred technique for introducing dopants into a silicon substrate. Conventionally, the junction depth is reduced by reducing the implantation energy, causing a reduction in the thickness implanted with the dopant. Theoretically, modern industrial implanters can provide sufficiently shallow dopant profiles, by implanting with energies of less than 1 keV. In practice, however, the junction depths which can be obtained are much greater than those predicted on the basis of the implantation energy alone, owing to phenomena such as channelling (channelling of the implanted ions into the crystal matrix) and transient enhanced diffusion (TED). TED is caused by the interaction between the dopant and the lattice damage caused by the implantation (self-interstitial point defects) during the thermal process of fast post-implantation annealing (required for elimination of the damage and electrical activation of the dopant), and is characterized by an increase even of several orders of magnitude of the diffusivity of the dopant and a consequent considerable increase in the junction depth [Stolk, Napolitani].

TED makes it extremely difficult, if not impossible, to control the distribution in depth of the dopant, and therefore the junction depth, simply by reducing the implantation energy. Moreover, the presence of TED makes it necessary to reduce the implantation energy, thus reducing the efficiency of the production lines for the devices (the current obtainable in an implanter generally decreases with the energy) and increasing production costs.

TED also causes a lateral enhanced diffusion of the dopant from the source and drain regions (formed by ion implantation) towards the gate of a CMOS device, thus compromising the width of the gate in a way which is difficult to control.

Effective methods of eliminating or reducing TED and channelling are therefore required for the production of shallow junctions by ion implantation in future generations of devices.

Pre-amorphization by ion implantation (by using non-electrically active species such as silicon, germanium and fluorine, for example) before the implantation of the dopant completely eliminates the channelling tails and eliminates the production of point defects by the implantation of the dopant. However, in addition to creating an amorphous surface layer in the crystalline substrate, the pre-amorphization implantation creates a large number of defects (particularly self-interstitial ones) beyond the amorphous/crystalline interface (called end of range (EOR) defects), which, during the subsequent thermal processes of recrystallization and electrical activation, diffuse towards the surface, interacting with the dopant and causing it to undergo transient enhanced diffusion [Jones, Robertson]. Although in some conditions the junctions produced by pre-amorphization implantation are shallower, usually this method, because of the significant TED and the large number of extended defects which it causes, cannot provide a solution for the formation of extremely shallow junctions.

In the patent literature, EP-A-0 806 794 describes a method for producing shallow doped regions in a semiconductor substrate by pre-amorphization and ion implantation; the method comprises the sub-amorphization implantation of a non-electrically active element such as silicon or germanium before the implantation of a dopant. The amorphization implantation energy is optimized to achieve the desired dopant profile.

U.S. Pat. No. 6,074,937 describes a process for producing high-density semiconductors, comprising shallow junctions in which lightly doped regions are implanted in an amorphous region of the semiconductor substrate to reduce the TED in the subsequent activation heat treatment; before the activation heat treatment, a sub-surface non-amorphous region is formed to eliminate the end of range (EOR) defects in the crystallization of the amorphous region containing the lightly doped regions.

U.S. Pat. No. 6,251,757 describes a process for fabricating a highly activated shallow doped junction in a semiconductor substrate, in which a first implantation with silicon ions or germanium ions is carried out in a surface of the semiconductor substrate to form a pre-amorphization junction having a predetermined depth, and a subsequent implantation with n- or p-type dopant is carried out at the pre-amorphization junction, after which the substrate is subjected to RTA (rapid thermal annealing) heat treatment to recrystallize the pre-amorphization junction.

EP-A-1 096 552 describes an implantation method designed to permit the control of the effective dose even in ion implantation at extremely low energy, and comprising a first stage of pre-amorphization ion implantation to produce an amorphous surface layer, a second stage of cleaning the semiconductor surface to eliminate oxidized films, and a third stage of low-energy ion implantation for forming a shallow junction.

The introduction of replacement carbon into the crystalline silicon matrix, to make use of its property of trapping self-interstitials, is one method which has been developed to reduce TED [Stolk 95].

U.S. Pat. No. 6,153,920 describes a method for controlling the diffusion of atoms of dopant, such as boron, phosphorus and arsenic, implanted in a semiconductor substrate, which comprises the incorporation of carbon in a region of the substrate at a depth below the space-charge layer of the semiconductor device.

However, the presence of carbon in the active regions of the devices is undesirable, because it degrades the electrical properties of the material [Stolk 95, Ban] and complicates the electrical activation of the dopant [Priolo].

In the present state of the art, there is no way of eliminating TED completely. The best developed method for producing shallow junctions is that of pre-amorphization in suitable conditions, but at present this does not enable sufficiently shallow junctions to be made for the most advanced technological nodes [Stolk 01]. A method for completely eliminating TED could have important technological applications in the field of semiconductors and the industrial treatment of semiconductors, and particularly in the formation of shallow junctions by ion implantation and in the production of CMOS devices.

A first object of the invention is therefore a method for suppressing TED in a surface region having a certain thickness of a semiconductor substrate, as defined in the following claims. The method has two objectives:
a) complete suppression of TED;
b) production of an electrically active doped surface region with a negligible presence of undesired impurities.

Another subject of the invention, defined in the following claims, consists in a process for producing a semiconductor device, having a shallow doped region, by using the TED suppression method cited previously.

Further subjects of the invention are semiconductor devices which can be produced by the methods and processes according to the invention, and also a semiconductor device which can be used as an intermediate product for making more complex semiconductor devices.

Further advantages and characteristics of the invention will be made clear by the following detailed description, provided with reference to the attached drawings and to a specific example of embodiment.

In the drawings,

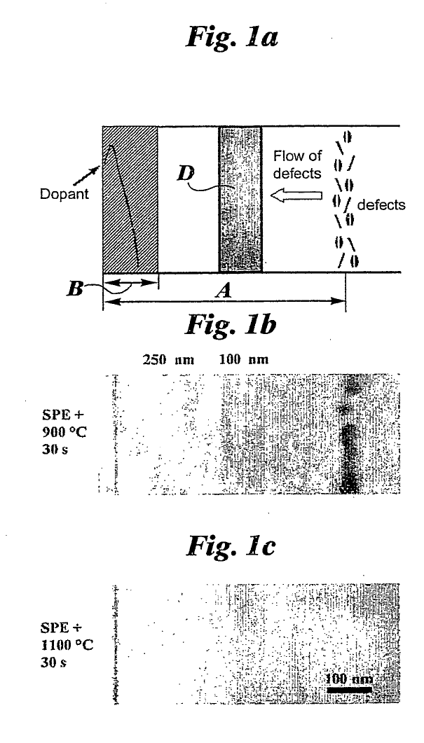

FIG. 1: (a) schematic description of the experiment; transmission electron microscope (TEM) images of a cross section of the specimen with carbon after heat treatment at 900° C. (b) and 1100° C. (c);

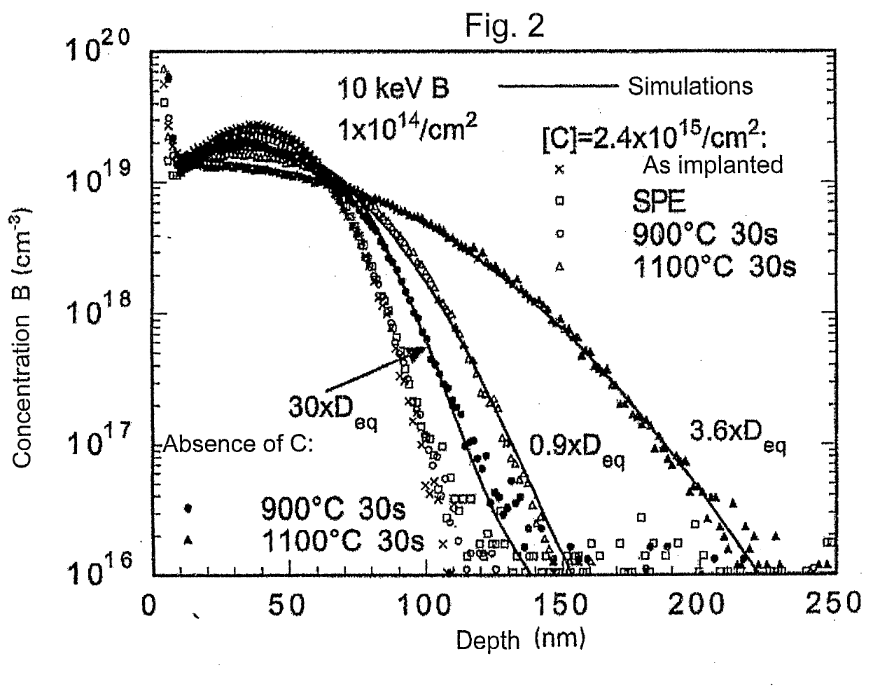

FIG. 2: profiles obtained by secondary ion mass spectroscopy (SIMS) of B implanted at 10 keV, dose 1×10¹⁴/cm² in pre-amorphized Si, before (x) and after (□) solid phase epitaxy (SPE), after SPE and rapid thermal annealing (RTA) at 900° C. for 30 seconds in a specimen with (◯) and without (●) C, and after SPE and RTA at 1.100° C. for 30 seconds in a specimen with (Δ) and without (▴) C; the simulated profiles are illustrated as continuous lines, together with the mean diffusivity used in the calculations;

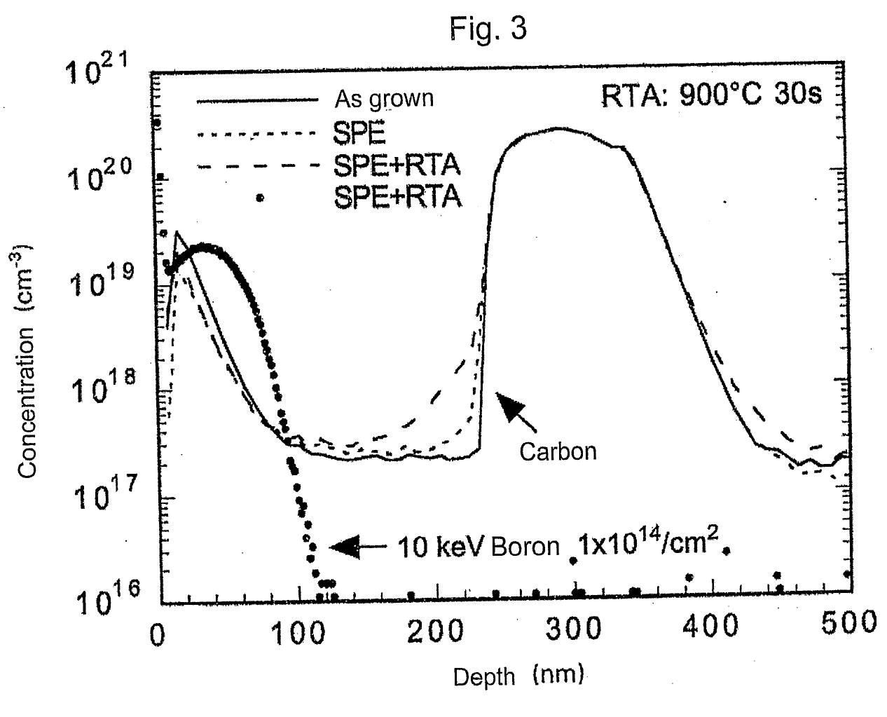

FIG. 3: SIMS profiles of carbon before (continuous line) and after (dotted line) SPE, and after SPE and RTA at 900° C. for 30 seconds (dashed line) compared with the profile B after SPE and RTA at 900° C. (◯).

With reference to FIG. 1, a silicon substrate is prepared in such a way as to have a surface region having a certain thickness A consisting of amorphous silicon on top of the crystalline substrate. This region can be produced, for example, by implanting silicon or germanium into crystalline silicon, or by depositing amorphous silicon on top of a substrate of crystalline silicon.

This substrate is prepared in such a way that it also has a surface region of thickness B, smaller than the thickness A, which is rich in dopant which has been introduced, for example by ion implantation before or after the forming of the amorphous layer. The effectiveness of the invention is limited to the case of dopants whose diffusivity depends on the concentration of self-interstitial point defects, these dopants including, for example, boron (other relevant dopants having this characteristic are phosphorus and arsenic).

The method also comprises the introduction of a certain quantity of an element X having the following properties:
a) it effectively traps self-interstitials;
b) it must be such that its diffusion can be kept at insignificant values within a sufficiently wide surface region throughout the process;

One example of an element with these properties is carbon.

The element X must be concentrated in a layer, namely the region D, interposed between the dopant-rich region and the interface between the amorphous and crystalline substances. The region D is thus spatially separated from the dopant-rich region. X can be introduced, for example, by a suitable deposition carried out before the amorphization implantation, or by ion implantation (and heat treatments if required) before or after the amorphization implantation, or by ion implantation after the deposition of an amorphous layer, or by deposition during the deposition of the amorphous layer.

The material is then subjected to a cycle of heat treatments to recrystallize the amorphous layer. This process, performed in different stages if required, is characterized by a thermal balance which is low enough not to allow a significant migration of any excess self-interstitials which may be present in the material, and is also such that it produces a negligible equilibrium diffusion of the dopant and of the element X. The result of this process, therefore, is the recrystallization of the material without the production of any diffusion of the dopant or of the element X, and without significant diffusion of any excess self-interstitials. The latter, if present, are located at the original amorphous/crystalline interface, in other words beyond the layer rich in the element X.

This structure must be stable when exposed to subsequent heat treatments which are required for the thermal activation of the dopant (the recrystallization process does not generally ensure complete activation of the dopant) or which are required by subsequent stage of the production of devices. In these heat treatments, the self-interstitial defects normally diffuse towards the surface, causing TED of the dopant present in the region B.

The method proposed here consists in the total suppression of this flow of interstitials by means of the element X present in the region D. Thus a complete electrical activation of the dopant is achieved without any undesired diffusion.

Owing to the complete suppression of the flow of self-interstitials by the region D, there will be no anomalous diffusion of the element X towards the surface. This diffusion will therefore be the equilibrium diffusion, and can be controlled by suitably optimizing the overall thermal process in such a way as to ensure an adequate spatial separation between the region rich in the element X and the doped region.

The method can comprise the alternative embodiment in which the recrystallization and electrical activation of the dopant take place in a single thermal process.

The method can also comprise the case in which the substrate or parts thereof are made from silicon alloys, for example SiGe or SiGeC.

### EXAMPLE

Molecular beam epitaxy (MBE) was used to grow on silicon a carbon (C)—enriched silicon layer with a thickness of 100 nm, acting as a trap element with a C concentration of 2.4×10²⁰/cm³, corresponding to a total C dose of 2.4×10¹⁵/cm². The layer was covered with a covering layer of pure silicon with a thickness of 250 nm. During the growth, the temperature of the substrate was held at 500° C. A second similar specimen was grown without the C enrichment, as a control.

Both specimens were then amorphized from their surfaces to a depth of approximately 550 nm by ion implantation of Si with an energy of 250 keV and a dose of 3×10¹⁵/cm², at the temperature of liquid nitrogen, and were then implanted with boron with an energy of 10 keV and a dose of 1×10¹⁴/cm². After solid-phase epitaxy (SPE), carried out by annealing in a furnace at 450° C. for 30 minutes and at 700° C. for 30 minutes under a flow of nitrogen, the original structure was recovered with a good crystalline quality, as verified by Rutherford Back-scattering Spectrometry-Channelling and with 100% of replacement C atoms, as verified by high-resolution X-ray diffraction analysis (HRXRD) and by resonant Back-scattering Spectrometry-Channelling analysis.

Finally, isochronal rapid thermal annealing (RTA) was carried out at 900 and 1100° C. for 30 seconds on these specimens which had been subjected to regrowth.

The chemical concentration depth profiles of C and B were then determined by secondary ion mass spectrometry (SIMS), using a CAMECA IMS-4f instrument, with an analysing beam of 3 keV O₂⁺ or 14.5 keV Cs⁺, collecting, respectively, secondary ions B⁺ or C⁻. The HRXRD (004) oscillation curves were determined by using a Philips MRD diffractometer in standard conditions (Bartels monochromator in Ge (220) setting, Cu tube at 40 kV and 40 mA). The activation of the dopant in the specimens was evaluated by measuring the sheet resistance with a four-point probe apparatus. The extended defects caused by the pre-amorphization implantation were characterized by transmission electron microscopy (TEM).

The excess interstitials left beyond the original amorphous-crystalline interface after the SPE cycle will develop into complex agglomerates during the subsequent RTA process. The formation and dissolution of the aforesaid defects will maintain a flow of interstitials towards the surface for a certain time, causing TED of the boron implanted near the surface. In the experiment which was conducted, the layer rich in replacement carbon was positioned between the EOR damage and the boron, in such a way as to trap the interstitials flowing towards the surface and consequently to suppress the TED.

FIGS. 1b and 1c show the TEM images of the cross section of the carbon-containing specimen, after annealing at 900° C. and at 1100° C. respectively. After 30 seconds at 900° C., there was complete dissolution of the {311} defects (FIG. 1b) which are the most significant source of interstitials inducing TED. However, a large number of dislocation loops of the interstitial type were still observed; these can act as reservoirs for a large number of interstitials. These defects are completely dissolved after 30 seconds at 1100° C., to the extent that no more EOR defects are visible (FIG. 1c).

These defects are known to be highly stable and capable of storing the excess interstitials without releasing them, even after aggressive heat treatment processes at 1000° C., and thus their presence would not constitute a problem for CMOS planar technology. RTA treatment at 1100° C. was carried out in order to verify the capacity of the C-rich layer to block the interstitials until the dissolution of the EOR defects was complete.

FIG. 2 shows the SIMS concentration profiles of boron implanted with an energy of 10 keV, at a dose of 1×10¹⁴/cm² in pre-amorphized silicon before and after SPE for the carbon-containing specimen (identical profiles were found for the control specimen) and after SPE with the addition of RTA at 900° C. or 1100° C. for 30 seconds both for the carbon-containing specimen and for the control specimen. As shown in FIG. 2, all the profiles after RTA were also simulated in a satisfactory way by solving the Fick's law equation, using as the initial data the profile measured by SIMS after SPE and taking as the free parameter a diffusion coefficient which is constant with time and depth. Without carbon, the dissolution of the {311} defects causes significant TED. For example, as shown in FIG. 2, the diffusion in the control specimen was simulated in a satisfactory way for the RTA process carried out for 30 seconds at 900° C., assuming a mean diffusivity greater by a factor of 30±10 than the equilibrium value.

As demonstrated in FIG. 2, the presence of carbon has a significant effect on the diffusion of the boron. The profile after 900° C., in the presence of the carbon-rich layer, compatibly with the equilibrium diffusion, is not distinguishable from the specimen after SPE. Thus a carbon-rich silicon layer with a C dose of 2.4×10¹⁵/cm² completely suppresses the TED produced by the complete dissolution of {311} defects of the EOR damage. This, combined with the fact that the diffusion during SPE is extremely low, results in a limited widening of the profile during the whole process (in other words from the specimen immediately after implantation to the specimen after SPE and RTA), causing a widening of less than 3 nm at a concentration level of 1×10¹⁷/cm³.

The profiles in FIG. 2 after 30 seconds at 1100° C. show what happens after complete dissolution of the EOR defects. A very high diffusion was observed in the specimen without C, supported by the complete dissolution of the EOR damage. The increase in diffusion during RTA for 30 seconds at 1100° C. was estimated to be 3.6±0.5. In this case also, the introduction of the C significantly suppresses the diffusion, as shown by the specimen with C, where the increase in diffusion was 0.9±0.2, in other words the mean diffusivity is compatible with the equilibrium value. Thus the C-rich layer completely prevents the flow of interstitials, also generated by the total dissolution of the EOR damage.

In order to produce a shallow junction, the B must be electrically active. An analysis was carried out with a four-point probe, in order to measure the sheet resistance and thus evaluate the activation of the dopant. If it was completely active, the boron in the C-containing specimen after SPE or after SPE and RTA at 900° C. would produce a sheet resistance of approximately 830 Ω/□. After SPE, a value of 1240 Ω/□ was found, indicating that the process of regrowth was not sufficient to completely activate the B. On the other hand, complete electrical activation was reached after SPE followed by RTA at 900° C. for 30 seconds, in which case a sheet resistance of 850±50 Ω/□ was found.

The question is whether the carbon-rich layer will be superimposed on the profile of the B, owing to the diffusion of C which can occur during the RTA process required for complete activation of the B, in other words RTA for 30 seconds at 900° C. This superimposition can severely impair the electrical properties of the junction. FIG. 3 shows the C profiles before and after SPE, and after SPE and RTA at 900° C., and compared with the B profile after SPE and RTA at 900° C. The SPE process leaves the C profile virtually unaltered, while a diffusion tail is seen in the silicon covering layer after 30 seconds at 900° C. This tail starts at a concentration level of approximately 2×10 ¹⁸/cm³ and falls to the SIMS base level of 2×10¹⁷/cm³ at a depth of approximately 120 nm. Consequently, the C diffusing to the outside of the carbon-rich layer will certainly be superimposed on the B profile, but well below the concentration level of 2×10¹⁷/cm³, in other words less by more than an order of magnitude than the concentration of C used by P. A. Stolk et al. [Stolk 95]. It should be emphasized that the significant surface peak of C with a pronounced tail does not correspond to a real contamination of C in the substance.

In fact, it is a well-known SIMS artefact, produced during analysis by the relocation, by sputtering beam, of the C contamination which is always present on the surface of Si exposed to air. Similar considerations apply to the deeper interface of the carbon-rich layer which is artificially widened exponentially towards the substrate by the action of the sputtering beam. In fact, the exponential decay of this interface has the same slope as the characteristic found at the surface. It can therefore be concluded that, after 30 seconds at 900° C., the boron is totally active without any TED, and moreover the carbon layer remains well separated spatially from the dopant.

In conclusion, the experiment demonstrates that the crystalline nature of the material can be recovered fully and the dopant can be activated completely with total suppression of TED, by introducing a C-rich silicon layer between the boron implanted in pre-amorphized silicon and the EOR damage. This method can therefore be considered for the fabrication of ultra-shallow junctions for future generations of devices.

In particular, the process according to the invention provides the following advantages:
a) owing to the complete suppression of TED, the diffusion of the dopant throughout the process is simply the equilibrium diffusion, which can be modelled conventionally and controlled to keep it at negligible levels. With this method, the dopant profile can be controlled, for example, simply by varying the implantation energy and dose, without any post-implantation diffusion.
b) The method can be used to form shallower junctions than those formed by the present methods.
c) The method can be used to create lateral profiles of active dopant which are sharper than those which can be obtained by present technology, thus permitting better control of the gate width of CMOS devices, and particularly narrower gates.
d) This method could be used to produce present-day devices, such as those to be produced in the near future, by using higher implantation energies and therefore with greater efficiency and lower costs.
e) Theoretically, this method could make it possible, by using modern industrial implanters capable of implanting boron with an energy of up to 0.2 keV, to form junctions with depths of less than 15 nm, as required for the 0.04 μm technological node in 2011. The importance of this result will be understood when it is realized that no methods are yet known for forming source/drain junctions for CMOS devices even for the 0.09 μm node in 2004.
f) Since the element acting as the trap is kept spatially separate from the doped region, all problems relating to the dopant-trap interaction are eliminated, particularly the electrical inactivation of the dopant due to the formation of agglomerates between the dopant and the trap element. Problems relating to the presence of the trap element in the active region, for example the degradation of the electrical properties of the silicon and the junction, are also eliminated.

### REFERENCES

[Road] International Technology Roadmap for Semiconductors (Semiconductor Industry Association, Austin, Tex., 2000).
[Stolk 95] P. A. Stolk, D. J. Eaglesham, H.-J. Gossmann, J. M. Poate, Appl. Phys. Lett. 66, 1370 (1995).
[Stolk 97] P. A. Stolk, H.-J. Gossmann, D. J. Eaglesham, D. C. Jacobson, C. S. Rafferty, G. H. Gilmer, M. Jaraiz, J. M. Poate, H. S. Luftman and T. E. Haynes, J. Appl. Phys. 81, 6031(1997) and indicated references.
[Stolk 01] P. A. Stolk “Shallow p-type junctions for sub-100 nm CMOS”, Dissertation presented at MRS Spring Meeting 2001, San Francisco 16-20 Apr. 2001
[Napolitani] E. Napolitani, A. Carnera, E. Schroer, V. Pri-vitera, F. Priolo, S. Moffatt, Appl. Phys. Lett. 75, 1869 (1999).
[Jones] K. S. Jones, L. H. Zhang, V. Krishnamoorthy, M. Law, D. S. Simons, P. Chi, L. Rubin, R. G. Elliman, Appl. Phys. Lett. 68, 2672 (1996).
[Robertson] L. S. Robertson, M. E. Law, K. S. Jones, L. M. Rubin, J. Jackson, P. Chi, D. S. Simons, Appl. Phys. Lett. 75, 3844 (1999).
[Ban] I. Ban, M. Öztürk, K. Christensen, D. M. Maher, Appl. Phys. Lett. 68, 499 (1996).
[Priolo] F. Priolo, G. Mannino, M. Miccichè, V. Privitera, E. Napolitani, A. Carnera, Appl. Phys. Lett. 72, 3011 (1998).

1. Method for suppressing transient enhanced diffusion (TED) of a dopant implanted in a thin surface layer of a semiconductor substrate, caused by the interaction between the dopant and the lattice damage produced by the implantation during the thermal process of post-implantation annealing, characterized in that the aforesaid thermal process is carried out on a crystalline semiconductor provided with an amorphous surface layer in which the said dopant is implanted and which has a layer rich in a trap element which effective traps self-interstitial point defects, the layer being spatially separated from the dopant-rich surface layer and interposed between said dopant-rich surface layer and the interface between the amorphous and crystalline regions of the substrate.

2. Method according to claim 1, in which the amorphous layer is produced by ion implantation in the crystalline substrate.

3. Method according to claim 2, in which the layer rich in the trap element, spatially separate from the dopant-rich layer, is produced by deposition before or after the amorphization implantation.

4. Method according to claim 2, in which the layer rich in the trap element is produced by ion implantation before or after the amorphization implantation.

5. Method according to claim 1, in which the amorphous layer is produced by deposition of amorphous silicon on the crystalline substrate.

6. Method according to claim 5, in which the layer rich in the trap element is produced by ion implantation after the deposition of the amorphous layer.

7. Method according to claim 5, in which the layer rich in the trap element is produced by deposition during the deposition of the amorphous layer.

8. Method according to claim 1, in which the dopant-rich surface layer, having a thickness less than the thickness of the amorphous layer, is produced by ion implantation of the dopant before or after the formation of the amorphous layer.

9. Method according to claim 1, in which the trap element is carbon.

10. Method according to claim 9, in which the said layer rich in the trap element comprises carbon at a concentration ranging from 1×1018/cm3 to 1×1021/cm3.

11. Method according to claim 1, comprising the operations of:
a) growing a layer of carbon-rich silicon on the crystalline semiconductor substrate,
b) covering the layer produced at a) with a layer of silicon,
c) amorphizing a surface layer at a depth greater than the depth of the carbon-rich layer,
d) ion implantation of a dopant in a thin surface layer having a depth such that the dopant layer is spatially separated from the carbon-rich layer, and
e) applying annealing heat treatment or a sequence of annealing heat treatments.

12. Method according to claim 1, in which the heat treatment or at least part thereof is carried out in conditions such that the amorphous layer is recrystallized.

13. Method according to claim 12, in which the heat treatment is carried out in conditions such that the dopant is electrically activated.

14. Method according to claim 1, in which the heat treatment or part thereof is carried out in such a way that no significant superimposition is caused between the dopant and the trap element.

15. Process for forming a shallow doped region in a semiconductor, comprising the operations of:
implanting a dopant in a thin surface layer of the semiconductor and carrying out one or more heat treatments to reconstruct the crystalline structure of the semiconductor and/or to electrically activate the dopant, characterized in that the aforesaid heat treatments are applied to a crystalline semiconductor having an amorphous surface layer, in which the said dopant is implanted, and also having a layer rich in a trap element capable of trapping self-interstitial point defects, this layer being spatially separated from the dopant-rich surface layer and interposed between the said dopant-rich surface layer and the interface between the amorphous and crystalline regions of the substrate.

16. Process according to claim 15, in which the amorphous layer is produced by ion implantation in the crystalline substrate.

17. Process according to claim 16, in which the layer rich in the trap element, spatially separate from the dopant-rich layer, is produced by deposition before or after the amorphization implantation.

18. Process according to claim 16, in which the layer rich in the trap element is produced by ion implantation before or after the amorphization implantation.

19. Process according to claim 15, in which the amorphous layer is produced by deposition of amorphous silicon on the crystalline substrate.

20. Process according to claim 19, in which the layer rich in the trap element is produced by ion implantation after the deposition of the amorphous layer.

21. Process according to claim 19, in which the layer rich in the trap element is produced by deposition during the deposition of the amorphous layer.

22. Process according to claim 15, in which the dopant-rich surface layer, having a thickness less than the thickness of the amorphous layer, is produced by ion implantation of the dopant before or after the formation of the amorphous layer.

23. Process according to claim 15, in which the trap element is carbon.

24. Process according to claim 23, in which the said layer rich in the trap element comprises carbon at a concentration ranging from 1×1018/cm3 to 1×1021/cm3.

25. Process according to claim 15, comprising the operations of:
a) growing a layer of carbon-rich silicon on the crystalline semiconductor substrate,
b) covering the layer produced at a) with a layer of silicon,
c) amorphizing a surface layer by ion implantation at a depth greater than the depth of the carbon-rich layer,
d) ion implantation of a dopant in a thin surface layer having a depth such that the dopant layer is spatially separated from the carbon-rich layer, and
e) applying annealing heat treatment or a sequence of annealing heat treatments.

26. Process according to claim 15, in which the heat treatment or at least part thereof is carried out in conditions such that the amorphous layer is recrystallized.

27. Process according to claim 26, in which the heat treatment is carried out in conditions such that the dopant is electrically activated.

28. Process according to claim 15, in which the heat treatment or part thereof is carried out in such a way that no significant superimposition is caused between the dopant and the trap element.

29. Semiconductor device which can be produced by a process according to claim 15.

30. Intermediate semiconductor device having a thin surface layer in which a dopant is implanted and designed to be subjected to annealing heat treatments to reconstruct the crystalline structure of the semiconductor and/or to electrically activate the dopant, characterized in that the said intermediate device comprises a crystalline semiconductor with an amorphous surface layer, in which is implanted the said dopant, and a carbon-rich layer which is spatially separated from the dopant-rich surface layer and is interposed between the said surface layer and the interface between the amorphous and crystalline regions of the substrate.
